(19) United States
(12) Patent Application Publication
(10) Pub. No.: US 2012/0038385 A1
(43) Pub. Date: Feb. 16, 2012

(54) IN-PROCESS MEASUREMENT APPARATUS

(75) Inventors: David Eaglesham, Perrysburg, OH (US); Markus Gloeckler, Perrysburg, OH (US)

(73) Assignee: FIRST SOLAR, INC, Perrysburg, OH (US)

(21) Appl. No.: 13/208,087

(22) Filed: Aug. 11, 2011

Related U.S. Application Data
(60) Provisional application No. 61/373,676, filed on Aug. 13, 2010.

(51) Int. Cl. G01R 31/26; G01R 31/28; H01L 31/18

(52) U.S. Cl. 324/761.01; 29/593

(57) ABSTRACT

An in-process measurement apparatus can be used to determine characteristics of a photovoltaic module. Capacitance measurements of the photovoltaic module are conducted before, during, or after execution of a high-potential leakage test, a performance test, or other tests of the module. The capacitance measurements are used to determine the characteristics of the photovoltaic module, including information regarding depletion width, doping density, film layer thickness, trap concentrations and absorber thickness. The apparatus can also be used to ensure that photovoltaic modules conform to product specifications.

### CROSS-REFERENCE TO RELATED APPLICATIONS

This application claims priority to U.S. Provisional Application No. 61/373,676 filed on Aug. 13, 2010, the entirety of which is incorporated herein by reference.

### FIELD OF THE INVENTION

The present invention relates to an in-process measurement apparatus and methods of using an in-process measurement apparatus.

### BACKGROUND OF THE INVENTION

Measurement tools can be used to evaluate electrical and mechanical properties of photovoltaic modules. In particular, measurement tools can be used to determine internal properties of a semiconductor within a photovoltaic module. For instance, by measuring capacitance of a thin film photovoltaic module, characteristics of a p-n junction can be determined. From these characteristics, the quality and performance of the photovoltaic module can be determined.

### BRIEF DESCRIPTION OF THE DRAWINGS

FIG. 1 is a side view of a photovoltaic module.

FIG. 2 is a perspective view of an in-process electrical test apparatus and a photovoltaic module.

FIG. 3 is a flow chart showing a method of manufacturing a photovoltaic module.

FIG. 4 is a flow chart showing a method of manufacturing a photovoltaic module.

FIG. 5 is a flow chart showing a method of manufacturing a photovoltaic module.

### DETAILED DESCRIPTION OF THE INVENTION

When manufacturing a photovoltaic module, it can be desirable to quantify characteristics of the module for quality control purposes. For example, it can be desirable to determine information about semiconductor layers within the module. In particular, obtaining information regarding depletion width, doping density, film layer thickness, trap concentrations, and absorber thickness can be useful. Module information can be acquired by implementing an in-process measurement apparatus. The apparatus can be used to ensure that each module conforms to product specifications. The photovoltaic modules can be tested at the end of the manufacturing process or at any point throughout the manufacturing process.

Capacitance measurements may be employed at any stage of the manufacturing process, ranging from a stage where the module is partially assembled to a stage where the module is completely assembled. Capacitance measurements may be conducted independently from other module testing, or it may be combined with other forms of testing. Capacitance measurements may be combined with other in-process tests such as, for example, a high-potential leakage test or a module performance test.

The high-potential leakage test can be performed within, a high-potential leakage test station. During the test procedure, a high voltage is applied to the module. The high-potential leakage test station includes all necessary instrumentation to perform the high-potential leakage test and also protects a User from electrical shock. Capacitance measurement capability may be incorporated into the high-potential leakage test station, thereby permitting capacitance measurements to be conducted while the module is in the station. Capacitance measurements may be conducted before, during, or after execution of the high-potential leakage test. By combining these two tests into the same test station, the time required for in-process module evaluation can be reduced.

The performance test can be performed within a performance test station. During the test procedure, the performance of the photovoltaic module is evaluated. The performance test station includes all necessary instrumentation to perform the performance test and also protects. Capacitance measurement capability may be incorporated into the performance test station, thereby permitting capacitance measurements to be conducted while the module is in the station. Capacitance measurements may be conducted before, during, or after execution of the performance test. By combining these two tests into the same test station, the time required for in-process module evaluation can be reduced.

To further streamline the manufacturing process, the aforementioned test stations may be combined into a single test station. The test station may include capacitance measurement capability, high-potential leakage test capability, and performance test capability.

In one aspect, a method for manufacturing a photovoltaic module may include providing a photovoltaic module and characterizing the photovoltaic module using capacitance measurements, where the photovoltaic module is at a stage in a manufacturing process ranging from partially assembled to fully assembled. The method may include placing the photovoltaic module in a high potential leakage test station and conducting a high potential leakage test on the photovoltaic module. The characterizing via capacitance measurements may be conducted while the photovoltaic module is in the high potential leakage test station. The method may include placing the photovoltaic module in a performance test station and conducting a performance test on the photovoltaic module. The characterizing via capacitance measurements may be conducted while the photovoltaic module is in the performance test station.

In another aspect, an in-process electrical test apparatus for a photovoltaic module may include an electrical power source and a capacitance measuring device. The electrical power source may include a first lead and a second lead. The capacitance measuring device may include a first capacitance lead and a second capacitance lead. The apparatus may be configured to perform capacitance measurements on a photovoltaic module. The apparatus may be disposed within a high-potential leakage test station. The apparatus may be disposed within a performance test station. The electrical power source may provide an alternating current between the first and second leads having a frequency ranging from 10 Hz to 100 MHz. The electrical power source may provide an alternating current between the first and second leads having a frequency ranging from 1 kHz to 200 kHz. The electrical power source may provide a direct current between the first and second leads. The electrical power source may provide a voltage between the first and second leads ranging from 50 micro-volts to 50 V. Preferably, the electrical power source provides a voltage between the first and second leads ranging from 5 mV to 50 V. The electrical power source may sweep a direct current voltage offset between the first and second leads from a starting value to an end value, where the starting value ranges from about −500V to about 500V and the ending value ranges from about −500V to about 500V.

In another aspect, a method of manufacturing a photovoltaic module may include providing an electrical test apparatus including an electrical power source and a capacitance measuring device. The method may include providing a photovoltaic module, providing electrical power from the electrical power source to the photovoltaic module through a first lead and a second lead, and measuring capacitance between a first capacitance lead and a second capacitance lead to determine a measured capacitance. The method may include placing the photovoltaic module in a high potential leakage test station and conducting a high potential leakage test on the photovoltaic module. The characterizing via capacitance measurements may be conducted while the photovoltaic module is in the high potential leakage test station. The method may include placing the photovoltaic module in a performance test station and conducting a performance test on the photovoltaic module. The characterizing via capacitance measurements may be conducted while the photovoltaic module is in the performance test station. The electrical power may include an alternating current having a frequency ranging from 10 Hz to 100 MHz. Preferably, the electrical power may include an alternating current having a frequency ranging from 1 kHz to 200 kHz. The e electrical power may include a direct current. The electrical power may include a voltage ranging from 50 micro-volts to 50 V. Preferably, the electrical power may include a voltage ranging from 5 mV to 50 V. The method may include determining a depletion width of a p-n junction disposed within the photovoltaic module, where the depletion width is determined using the measured capacitance between the first capacitance lead and the second capacitance lead. The method may include determining a doping density of a semiconductor layer disposed within the photovoltaic module, where the doping density is determined using the measured capacitance between the first capacitance lead and the second capacitance lead. The method may include determining a semiconductor layer thickness of a semiconductor layer disposed within the photovoltaic module, where the semiconductor layer thickness is determined using the measured capacitance between the first capacitance lead and the second capacitance lead. The method may include determining a trap concentration of a semiconductor layer disposed within the photovoltaic module, where the trap concentration is determined using the measured capacitance between the first capacitance lead and the second capacitance lead. The method may include identifying a non-conforming photovoltaic module based on the measured capacitance between the first capacitance lead and the second capacitance lead and removing the non-conforming photovoltaic module from an assembly line. The method may include sweeping a direct current voltage offset provided by the electrical power source from a starting value to an end value, where the starting value ranges from about −500V to about 500V and the end value ranges from about −500V to about 500V.

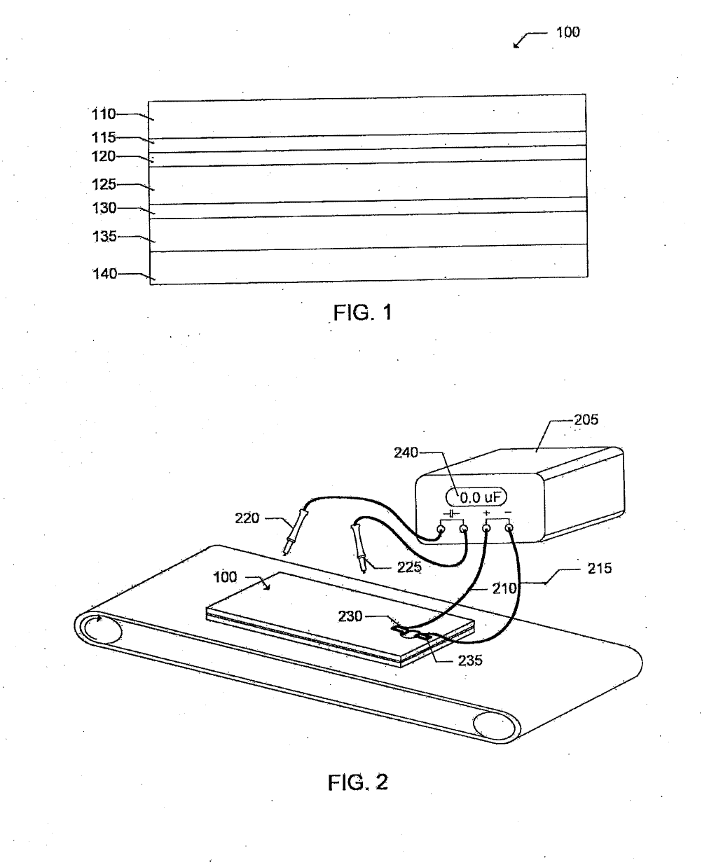

FIG. 1 shows a side cross-sectional view of an example photovoltaic module. Photovoltaic modules may be more sophisticated or less sophisticated than the module shown. For example, a less sophisticated module may omit several nonessential layers and still function adequately. Conversely, a more sophisticated module may include additional layers thereby providing enhanced performance or reliability. FIG. 1 is provided as an example of a photovoltaic module and, accordingly, is not limiting. Further, the apparatus and methods disclosed herein may be applied to any type of photovoltaic technology including, for example, cadmium telluride, cadmium selenide, amorphous silicon, and copper indium gallium (di)selenide (CIGS). Several of these photovoltaic technologies are discussed. in U.S. patent application Ser. No. 12/572,172, filed on Oct. 1, 2009, which is incorporated by reference in its entirety.

The photovoltaic module 100 may include a superstrate layer 110. The superstrate layer 110 may be formed from an optically transparent material such as soda-lime glass. In addition, isolating the glass superstrate 110 prior to assembly may prevent unwanted sodium diffusion. A transparent conductive oxide layer (TCO) 115 may be formed adjacent to the glass superstrate 110 and may serve as a front contact for the module. It is desirable to use a material that has high conductivity and high transparency, so the TCO layer 115 may include, for example, tin oxide, cadmium stannate, or indium tin oxide.

A buffer layer 120 may be formed adjacent to the TCO layer 115. The buffer layer 120 serves as a n-type layer. The buffer layer 120 may include a very thin layer of cadmium sulfide. For instance, the buffer layer 120 may be 0.1 microns thick. The buffer layer 120 may be deposited using any suitable thin-film deposition technique. A CdTe layer 125 may be formed adjacent to the buffer layer 120 and may serve as a p-type layer. A back contact 130 may be formed adjacent to the CdTe layer 125. Lastly, protective layers (e.g. 135, 140) may be formed to encapsulate the rear side of the module. For instance, a polymer layer 135 may be formed adjacent to the back contact layer 130, and a protective back substrate 140 may be formed adjacent to the polymer layer 135. The polymer layer 135 may include, for example, ethylene-vinyl acetate (EVA), and the protective back substrate 140 may include, for example, soda-lime glass.

The thin-film photovoltaic module may contain a p-type semiconductor layer adjacent to a n-type semiconductor layer. A p-n junction is formed where the two layers meet. The p-n junction may contain a depletion region characterized by a lack of electrons on the n-type side of the junction and a lack of holes (i.e. electron vacancies) on the p-type side of the junction. The width of the depletion region is a sum of the diffusion depth in the p-type layer added to the diffusion depth in the n-type layer. The respective lack of electrons and holes is caused by electrons diffusing from the n-type layer to the p-type layer and holes diffusing from the p-type layer to the n-type layer. As a result of the diffusion process, positive donor ions are formed on the n-type side and negative acceptor ions are formed on the p-type side.

The presence of a negative ion region near a positive ion region establishes a built-in electric field across the p-n junction. The potential of the built-in electrical field is dictated in part by the impurity concentrations in each layer and the diffusion depth of the impurities in each layer. For instance, by increasing the impurity concentration in a layer, the built-in potential may be increased. Similarly, by increasing the diffusion depth of impurities in a layer, the built-in potential may be increased. Therefore, knowing the diffusion depth and impurity concentration in each layer is vital when determining the built-in potential.

Capacitance measurements of the photovoltaic module provide information about internal properties of p-n junction within the photovoltaic module. For example, depletion width, doping density, film layer thickness, trap concentration, and absorber thickness may be derived from capacitance measurements. If the measured values are not within a desired range, the manufacturing process can be corrected before resources are wasted in constructing nonconforming products.

Depletion width can be determined by a simple capacitance measurement. The depletion width change due to the AC signal of the measurement will predominantly shift the edge of the lower doped material, typically, the p-type layer in the thin-film photovoltaic module. The measured capacitance can be translated into a depletion width using a formula for a thickness of a parallel plate capacitor assuming the dielectric constant of the absorber layer.

Doping or charge density can be determined by profiling capacitance versus direct current bias voltage. The derivation is presented in many introductory texts on semiconductor characterization.

Film layer thickness can be determined by measuring capacitance under reverse bias voltage, because at sufficient reverse bias the depletion region exceeds the thickness of the absorber layer. Once this condition is met the capacitance is independent of further voltage bias increase,

Trap concentrations can be determined by measuring capacitance under varying frequency. While shallow traps are capable of responding to AC signals of any frequency, deeper dopant levels or trap levels can only respond to signals of lower frequency. A charge density profile acquired at high frequency may correspond to the free carrier concentration. A charge density profile at low frequency may correspond to the sum of free carriers and deep traps. A subtraction of charge density profiles measured at high and low frequency may correlate to the density of deep levels.

An in-process method of testing a photovoltaic module may utilize an in-process measurement apparatus 205 as shown in FIG. 2. The electrical test apparatus 205 may include a power source capable of acting as a current source or a voltage source. The test apparatus 205 may include a first lead 210 and a second lead 215. The first lead 210 may be connected to a positive terminal 230 on the photovoltaic module and the second lead 215 may be connected to a negative terminal 235 on the photovoltaic module 100. The apparatus 205 may perform measurements during the manufacturing process before assembly of the module is completed. The apparatus 205 may perform measurements at the end of the manufacturing process with the purpose of quality control. At the end of the manufacturing line, the apparatus 205 may be integrated into an end-of-line test station that executes other standardized tests. As an example, the apparatus 205 may be incorporated into a station that performs current-voltage measurements that are used to determine photovoltaic module power.

The test apparatus 205 may be capable of providing a wide variety of outputs across the first and second leads (210, 215) of the power source to facilitate numerous capacitance tests. For example, the power source may be capable of providing direct current, alternating current at selectable frequencies, constant voltage, voltage sweeps with selectable sweep rates, or a combination of these current signals. The power source may provide alternating current with controlled voltage amplitude. In particular, the electrical power source may provide alternating currents with voltage amplitudes ranging from 50 micro-volts to 0.5 V when testing a single solar cell. However, when testing a photovoltaic module containing many cells connected in series, the voltage requirement may scale with the number of cells. For a module containing approximately 100 cells in a series connection, the power source may provide voltages ranging from 5 mV to 50 V. As noted above, the power source may provide alternating current, direct current, or a combination thereof. For example, the power source may provide alternating current having a frequency ranging from 10 Hz to 100 MHz. Preferably, the power source may provide alternating current ranging from 1 kHz to 1 MHz. In addition to the AC current, the power source may provide direct current bias voltage offset. The power source may provide bias voltage offsets from −500 V to 500 V. The power source may sweep the bias voltage offset from a starting value to an end value. The starting value and end value may range from −500V to 500V.

The test apparatus 205 may include a capacitance measuring device. The first and second capacitance leads (220, 225) may be connected to a first and second surface of the photovoltaic module, respectively. For instance, the first and second capacitance leads (220, 225) may be connected to the first and second terminals (230, 235) of the photovoltaic module 100.

The in-process measurement apparatus 205 may contain a digital display 240 that presents capacitance values during testing. The capacitance values shown on the display 240 may be used to identify non-conforming products, and a manual or an automated system may be used to remove non-conforming products from the assembly line. The values may also be transmitted to a computer system where they are stored in a database. The values stored in the database may be used to quantify product quality over time, thereby facilitating quality control measures.

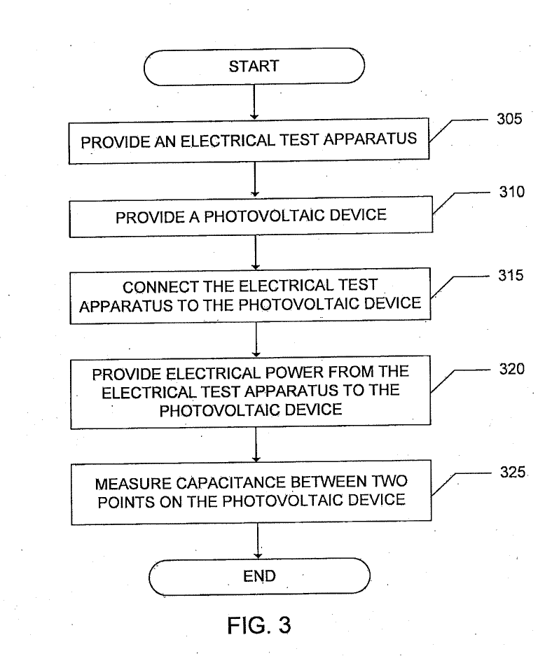

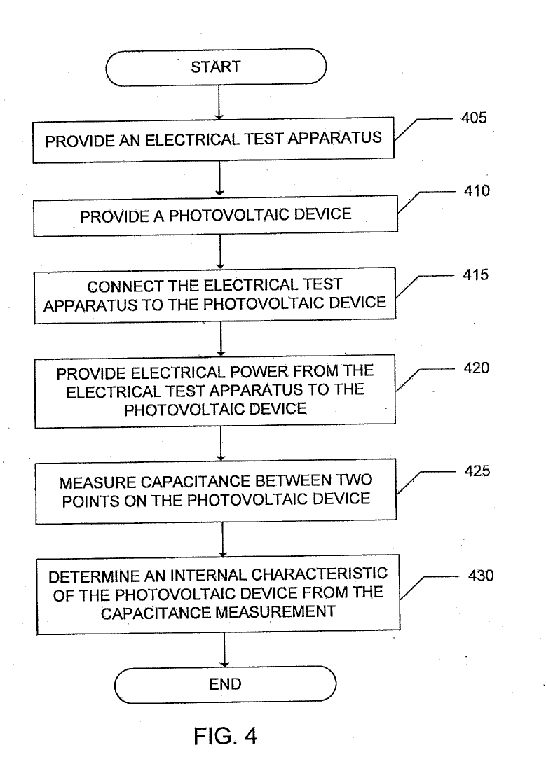

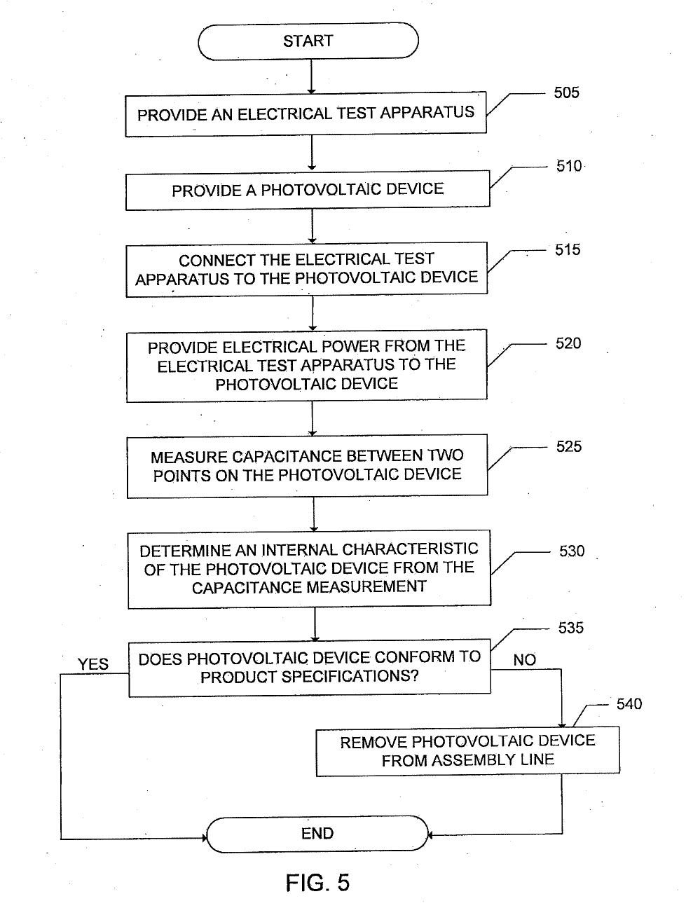

FIGS. 3-5 illustrate methods of manufacturing a photovoltaic module in accordance with the present disclosure. In each of the illustrated methods, an electrical test apparatus is provided (steps 305, 405, 505 in FIGS. 3, 4, 5, respectively). As described above, the electrical test apparatus may be configured to conduct a high-potential leakage test, a performance test, or both, as well as other tests. A photovoltaic device is provided for testing by the electrical test apparatus (steps 310, 410, 510 in FIGS. 3, 4, 5, respectively). The photovoltaic device is connected to the electrical test apparatus for testing (steps 315, 415, 515 in FIGS. 3, 4, 5, respectively). Electrical power is provided to the connected photovoltaic device from the electrical test apparatus (steps 320, 420, 520 in FIGS. 3, 4, 5, respectively). Once electrically powered, the capacitance between two points on the photovoltaic device is measured (steps 325, 425, 525 in FIGS. 3, 4, 5, respectively). In the embodiment illustrated by FIG. 3, the resulting capacitance measurements are themselves used to characterize the photovoltaic device. In the embodiments illustrated by FIGS. 4 and 5, the capacitance measurements are used to further determine an internal characteristic of the photovoltaic device (steps 430, 530 in FIGS. 4, 5, respectively). The determined internal characteristic could include a depletion width of a p-n junction disposed within the photovoltaic device, a doping density of a semiconductor layer disposed within the photovoltaic device, a semiconductor layer thickness of a semiconductor layer disposed within the photovoltaic device, or a trap concentration of a semiconductor layer disposed within the photovoltaic device. Additionally, as illustrated in FIG. 5, a determination may be made, based on the determined internal characteristics, whether the photovoltaic device conforms to product specifications (step 535). If the photovoltaic device does not conform, it can be removed from its assembly line (step 540).

The in-process measurement apparatus may be used to determine a variety of characteristics about the photovoltaic module based upon the measured capacitance. For instance, the method may include determining a depletion width of a p-n junction disposed within the photovoltaic module, determining a doping density of a semiconductor layer disposed within the photovoltaic module, determining a semiconductor layer thickness of a semiconductor layer disposed within the photovoltaic module, determining a trap concentration of a semiconductor layer disposed within the photovoltaic module, determining a free carrier versus deep trap contribution in a p-n junction disposed within the photovoltaic Module. The method may also include identifying a non-conforming photovoltaic module based on the measured capacitance between the first capacitance lead and the second capacitance lead and may further include removing the non-conforming photovoltaic module from an assembly line. In addition, the method may include storing the measured capacitance value in a database.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. It should also be understood that the appended drawings are not necessarily to scale, presenting a somewhat simplified representation of various features and basic principles of the invention.

What is claimed as new and desired to be protected by Letters Patent of the United States is:

1. A method for manufacturing a photovoltaic module, the method comprising:
providing a photovoltaic module; and
characterizing the photovoltaic module using capacitance measurements, wherein the photovoltaic module is at a stage in a manufacturing process ranging from partially assembled to fully assembled.

2. The method of claim 1, further comprising:
placing the photovoltaic module in a high potential leakage test station; and
conducting a high potential leakage test on the photovoltaic module.

3. The method of claim 2, wherein the characterizing via capacitance-voltage profiling is conducted while the photovoltaic module is in the high potential leakage test station.

4. The method of claim 1, further comprising:
placing the photovoltaic module in a performance test station; and
conducting a performance test on the photovoltaic module.

5. The method of claim 4, wherein the characterizing via capacitance-voltage profiling is conducted while the photovoltaic module is in the performance test station.

6. An in-process electrical test apparatus for a photovoltaic module, comprising:
an electrical power source, comprising:
a first lead; and
a second lead; and
a capacitance measuring device, comprising:
a first capacitance lead; and
a second capacitance lead,
wherein the apparatus is configured to perform capacitance measurements on a photovoltaic module.

7. The apparatus of claim 6, wherein the apparatus is disposed within a high-potential leakage test station.

8. The apparatus of claim 6, wherein the apparatus is disposed within a performance test station.

9. The apparatus of claim 6, wherein the electrical power source provides an alternating current between the first and second leads, and wherein the alternating current has a frequency ranging from 10 Hz to 100 MHz.

10. The apparatus of claim 6, wherein the electrical power source provides an alternating current between the first and second leads, and wherein the alternating current has a frequency ranging from 1 kHz to 1 MHz.

11. The apparatus of claim 6, wherein the electrical power source provides a direct current between the first and second leads.

12. The apparatus of claim 6, wherein the electrical power source provides a direct current voltage offset between the first and second leads, wherein the voltage amplitude ranges from −500 V to 500 V.

13. The apparatus of claim 6, wherein the electrical power source provides an alternating current with a voltage amplitude between the first and second leads, wherein the voltage amplitude ranges from 50 mV to 50 V.

14. A method of manufacturing a photovoltaic module, comprising:
providing an electrical test apparatus, comprising:
an electrical power source; and
a capacitance measuring device;
providing a photovoltaic module;
providing electrical power from the electrical power source to the photovoltaic module through a first lead and a second lead; and
measuring capacitance between a first capacitance lead and a second capacitance lead to determine a measured capacitance.

15. The method of claim 14, further comprising:
placing the photovoltaic module in a high potential leakage test station; and
conducting a high potential leakage test on the photovoltaic module.

16. The method of claim 15, wherein the characterizing via capacitance-voltage profiling is conducted while the photovoltaic module is in the high potential leakage test station.

17. The method of claim 14, further comprising:
placing the photovoltaic module in a performance test station; and
conducting a performance test on the photovoltaic module.

18. The method of claim 17, wherein the characterizing via capacitance-voltage profiling is conducted while the photovoltaic module is in the performance test station.

19. The method of claim 14, wherein the electrical power comprises an alternating current, and wherein the alternating current has a frequency ranging from 10 Hz to 100 MHz.

20. The method of claim 14, wherein the electrical power comprises an alternating current, and wherein the alternating current has a frequency ranging from 1 kHz to 1 MHz.

21. The method of claim 14, wherein the electrical power comprises a direct current.

22. The method of claim 14, wherein the electrical power comprises a direct current voltage offset ranging from −500 V to 500 V

23. The method of claim 14, wherein the electrical power comprises voltage ranging, from 5 mV to 50 V.

24. The method of claim 14, further comprising:
determining a depletion width of a p-n junction disposed within the photovoltaic module, wherein the depletion width is determined using the measured capacitance between the first capacitance lead and the second capacitance lead.

25. The method of claim 14, further comprising:
determining a doping density of a semiconductor layer disposed within the photovoltaic module, wherein the doping density is determined using the measured capacitance between the first capacitance lead and the second capacitance lead.

26. The method of claim 14, further comprising:
determining a semiconductor layer thickness of a semiconductor layer disposed within the photovoltaic module, wherein the semiconductor layer thickness is determined using the measured capacitance between the first capacitance lead and the second capacitance lead.

27. The method of claim 14, further comprising:
determining a trap concentration of a semiconductor layer disposed within the photovoltaic module, wherein the trap concentration is determined using the measured capacitance between the first capacitance lead and the second capacitance lead.

28. The method of claim 14, further comprising:
identifying a non-conforming photovoltaic module based on the measured capacitance between the first capacitance lead and the second capacitance lead; and
removing the non-conforming photovoltaic module from an assembly line.

29. The apparatus of claim. 6, wherein the electrical power source sweeps a direct current voltage offset between the first and second leads from a starting value to an end value, wherein the starting value ranges from about −500V to about 500V, and wherein the ending value ranges from about −500V to about 500V.

30. The method of claim 14, further comprising sweeping a direct current voltage offset provided by the electrical power source from a starting value to an end value, wherein the starting value ranges from about −500V to about 500V, and wherein the end value ranges from about −500V to about 500V.
